(19) United States
(12) Patent Application Publication
(10) Pub. No.: US 2025/0074227 A1
(43) Pub. Date: Mar. 6, 2025

(54) DC-DC ELECTRICAL CONVERTER AND MOBILITY VEHICLE COMPRISING SUCH A CONVERTER

(71) Applicant: Valeo eAutomotive Germany GmbH, Erlangen (DE)

(72) Inventors: Olivier GILET, Cergy Pontoise (FR); David CRAVO, Cergy Pontoise (FR)

(73) Assignee: Valeo eAutomotive Germany GmbH, Erlangen (DE)

(21) Appl. No.: 18/824,577

(22) Filed: Sep. 4, 2024

(30) Foreign Application Priority Data
Sep. 4, 2023 (FR) 2309269

(51) Int. Cl. B60L 53/22; H02M 1/00; H02M 3/00

(52) U.S. Cl. CPC B60L 53/22; H02M 1/0083; H02M 3/003; B60L 2210/10

(57) ABSTRACT

A converter includes an electrical conversion circuit having an input or output connector including two pins designed to receive the input voltage or to supply the output voltage and two flat auxiliary busbars. Each flat auxiliary busbar includes a first flat portion pressed and fixed against the positive pin and the negative pin, respectively, and a second flat portion, with these second flat portions being substantially parallel to each other with the first flat portion of the positive flat auxiliary busbar being pressed and fixed against a flat fixing portion of the positive pin, and the first flat portion of the negative flat auxiliary busbar being pressed and fixed against a flat fixing portion of the negative pin. Two positive and negative main busbars are connected to the electrical conversion circuit and respectively including flat portions respectively pressed and fixed against the second portions of the auxiliary busbars.

### TECHNICAL FIELD OF THE INVENTION

The present invention relates to a DC-DC electrical converter and to a mobility vehicle comprising such a converter.

A mobility vehicle is, for example, a motorised land vehicle, a train, an aircraft or even a drone. A motorised land vehicle is, for example, a motor vehicle, a motorbike, a motorised bicycle or even a motorised wheelchair.

### TECHNOLOGICAL BACKGROUND

A DC-DC electrical converter is known from the prior art comprising:
an electrical conversion circuit designed to convert a DC input voltage into a DC output voltage;
an input or output connector, comprising two flat pins, one positive and the other negative, designed to receive the input voltage or to supply the output voltage;
two main positive and negative busbars connected to the electrical conversion circuit.

In general, in order to connect the connector to the electrical circuit, the pins of the connector are pressed and fixed against the main busbars. Depending on the constraints for implementing the DC-DC electrical converter in its environment, the connector must have an orientation that is adapted to this environment. Thus, each time a new product with a DC-DC electrical converter is designed, the pins of the connector and/or the main busbars have to be modified in order to take into account this orientation. This leads to significant design and production costs.

Thus, it is recommended that a DC-DC electrical converter is provided that allows at least some of the aforementioned problems and constraints to be overcome.

### SUMMARY OF THE INVENTION

Therefore, a DC-DC electrical converter is proposed, comprising:
an electrical conversion circuit designed to convert a DC input voltage into a DC output voltage;
an input or output connector, called first connector, comprising:
   two pins, one positive and the other negative, designed to receive the input voltage or to supply the output voltage; and
   two flat auxiliary busbars, one positive and the other negative, with each flat auxiliary busbar comprising a first flat portion pressed and fixed against the positive pin and the negative pin, respectively, and a second flat portion, with these second flat portions being substantially parallel to each other, for example, coplanar, with the first flat portion of the positive flat auxiliary busbar being pressed and fixed against a flat fixing portion of the positive pin, and the first flat portion of the negative flat auxiliary busbar being pressed and fixed against a flat fixing portion of the negative pin and comprising a connection portion directly adjacent to the first portion and to the second portion; and
two positive and negative main busbars connected to the electrical conversion circuit and respectively comprising flat portions respectively pressed and fixed against the second portions of the auxiliary busbars.

Thus, by virtue of the invention, each time a new product is designed, only the auxiliary busbars need to be adapted to the desired orientation of the connector. The pins of the connector, as well as the main busbars, can remain unchanged.

The invention may further comprise one or more of the following optional features, in any technically feasible combination.

Optionally, the connection portion of each auxiliary busbar comprises a fold such that the first portion and the second portion of each auxiliary busbar together form a non-flat angle.

Thus, the auxiliary busbars may be easily adapted to the desired orientation by means of the fold.

Also optionally, the connection portion of the auxiliary busbars comprises a single fold connecting the first portion and the second portion.

This is an embodiment in which the auxiliary busbars are kept as simple as possible in order to facilitate their adaptation.

Also optionally, the connection portion of each auxiliary busbar is, in a current circulation direction within the auxiliary busbar, shorter than the first portion and the second portion.

Direction of circulation is understood to mean the direction of the current flowing through the auxiliary busbar.

This is an advantageous embodiment since it reduces the overall dimensions of the converter.

Also optionally, the second portions of the auxiliary busbars are fixed to the main busbars by screwing in a screwing direction that is substantially perpendicular to the second portions of the auxiliary busbars.

Also optionally, the first portions of the auxiliary busbars are fixed to the flat fixing portions of the pins by soldering.

Also optionally, the DC-DC electrical converter comprises a housing provided with a bottom with at least one flat part, and wherein the second portions of the auxiliary busbars are substantially parallel to the flat part of the bottom.

Also optionally, the flat fixing portions of the pins extend substantially parallel to each other one opposite the other and have opposite faces and outer faces, on the other side of the opposite faces, against which the first portions of the auxiliary busbars are pressed and fixed.

Also optionally, each pin comprises a flat end portion, with said flat end portions extending substantially parallel to each other one opposite the other, at a greater distance than the fixing portions, and the connector further comprises a magnetic torus surrounding the fixing portions of the pins.

Also optionally, the connector further comprises:
a first capacitor connected between the positive pin and an electrical ground, with this first capacitor being connected to the positive pin between the magnetic torus and its end portion; and/or
a second capacitor connected between the negative pin and the electrical ground, with this second capacitor being connected to the negative pin between the magnetic torus and its end portion.

Also optionally, the DC-DC electrical converter comprises another input or output connector, similar to the first connector. “Similar” means comprising:
two pins, one positive and the other negative, designed to receive the input voltage or to supply the output voltage; and
two flat auxiliary busbars, one positive and the other negative, with each flat auxiliary busbar comprising a first flat portion pressed and fixed against the positive pin and the negative pin, respectively, and a second flat portion, with these second flat portions being substantially parallel to each other, for example, coplanar, with the first flat portion of the positive flat auxiliary busbar being pressed and fixed against a flat fixing portion of the positive pin, and the first flat portion of the negative flat auxiliary busbar being pressed and fixed against a flat fixing portion of the negative pin.

The first and second flat portions of the auxiliary busbars of this other connector then together form an angle that is different from the angle between the first and second flat portions of the first connector, such that the second flat portions of this other connector are parallel to those of the first connector.

Also optionally, the other connector is an input connector and the first connector is an output connector.

Also optionally, the other connector is an output connector and the first connector is an input connector.

Also optionally, the positive pins and the negative pins of the two connectors are identical, in particular of the same shape.

A mobility vehicle is also proposed comprising a DC-DC electrical converter according to the invention.

### BRIEF DESCRIPTION OF THE FIGURES

The invention will be better understood by means of the following description, which is provided solely by way of an example and with reference to the appended drawings, in which:

FIG. 1 is a simplified view of a mobility vehicle in which the invention may be implemented;

FIG. 2 is a simplified three-dimensional view of a DC-DC electrical converter of the mobility vehicle of FIG. 1;

FIG. 3 is a three-dimensional view of a connector of the converter of FIG. 2;

FIG. 4 is a three-dimensional view of the connector of FIG. 3, from a different viewing angle and without a magnetic torus;

FIG. 5 is a three-dimensional view of an electromagnetic compatibility filter associated with the connector of FIGS. 3 and 4;

FIG. 6 is a three-dimensional view of the electromagnetic compatibility filter, isolated from the connector;

FIG. 7 is a view of the electromagnetic compatibility filter showing the locations of elements of a tool for fixing clamps;

FIG. 8 is a view similar to that of FIG. 7 without a vertical offset of two capacitors;

FIG. 9 is a three-dimensional view of the connector of FIGS. 3 and 4 and of another connector of the DC-DC electrical converter;

FIG. 10 is a three-dimensional view of the other connector and of an associated electromagnetic compatibility filter;

FIG. 11 is a series of three-dimensional views illustrating the successive steps of a method for manufacturing the other connector shown in FIGS. 9 and 10.

### DETAILED DESCRIPTION OF THE INVENTION

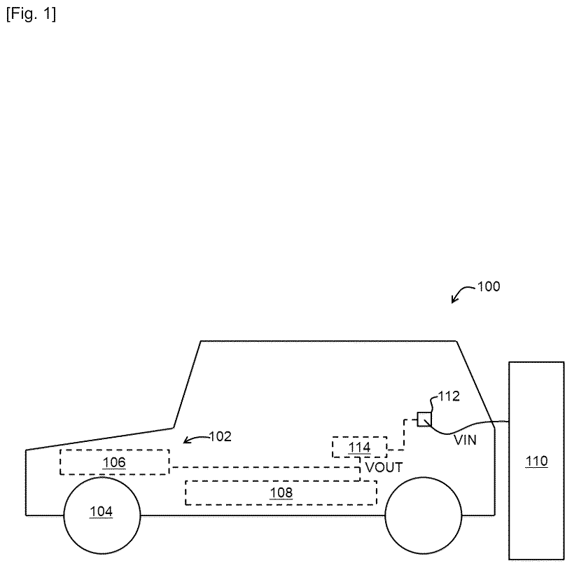

A mobility vehicle 100 in which the invention may be used will now be described with reference to FIG. 1.

The mobility vehicle 100 comprises a propulsion system 102, for example, drive wheels 104 and an electric motor 106 designed to drive the drive wheels 104. The mobility vehicle 100 further comprises a battery 108 designed to electrically power the electric motor 106.

To recharge the battery 108 at a recharging station 110 connected to an electrical distribution network (not shown), the mobility vehicle 100 further comprises an electrical socket 112 designed to be connected to the recharging station 110, as well as a DC-DC electrical converter 114 connected between the electrical socket 112 and the battery 108, in order to convert an input voltage VIN received from the recharging station 110 through the electrical socket 112 to an output voltage VOUT supplied to the battery 108.

Throughout the remainder of the description, the arrangement of the various elements of the converter 114 will refer to an arbitrary reference frame comprising a left-right axis X, a bottom-top axis Y and a front-back axis Z.

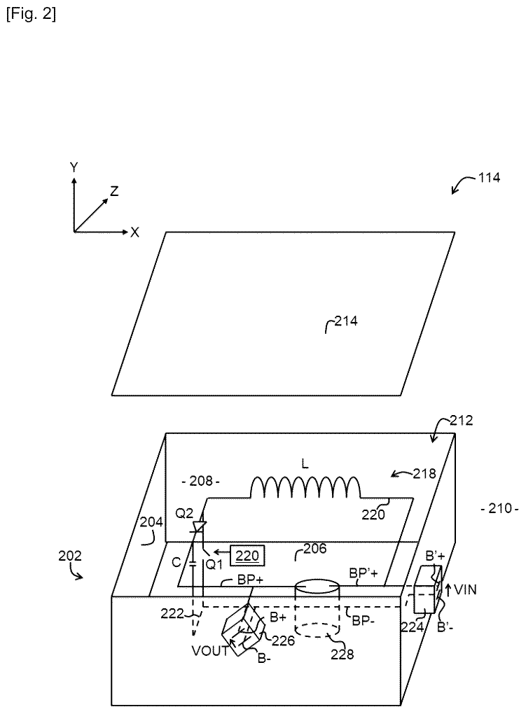

With reference to FIG. 2, the converter 114 will now be described in further detail.

The converter 114 firstly comprises a housing 202 comprising side walls 204 and a bottom 206, together defining an inner space 208 of the housing 202 and an outer space 210 of the housing 202. The side walls 204 may also define, opposite the bottom 206, an upper opening 212. In this case, the housing 202 may further comprise a cover 214 designed to close the upper opening 212.

The converter 114 further comprises an electrical conversion circuit 218 extending into the inner space 208 of the housing 202. The electrical conversion circuit 218 is designed to convert the input voltage VIN to the output voltage VOUT. For example, the converter 114 may be a parallel chopper (“boost converter” or even a “step-up converter”), in which case the conversion circuit 218 comprises, for example, a positive branch 220 and a negative branch 222, having an input side and an output side. The conversion circuit 218 comprises an inductor L on the positive branch, as well as a switch Q1 and a capacitor C, parallel with each other between the positive branch 220 and the negative branch 222, on the output side relative to the inductor L, and another switch Q2 on the positive branch, between the switch Q1 and the capacitor C, for example, a diode passing towards the capacitor C (with its cathode on the side of the capacitor C). The converter 114 then further comprises a control circuit 220 designed to control the switch Q to carry out the conversion.

To receive the input voltage VIN, the converter 114 further comprises an input connector 224 accessible from the outer space 210 so as to be connected to the external socket 112 by an electrical connection (not shown) having, at one of the ends thereof, a connector in addition to the input connector 224. The input connector 224 thus comprises two input pins B′+, B′−: the first pin B′+ is referred to as positive in order to receive the positive potential of the input voltage VIN and the second pin B′− is referred to as negative in order to receive the negative potential of the input voltage VIN.

To supply the output voltage VOUT, the converter 114 further comprises an output connector 226 accessible from the outer space 210 so as to be connected to the battery 108 by an electrical connection (not shown) having, at one of the ends thereof, a connector in addition to the output connector 226. The output connector 226 thus comprises two output pins B+, B−: the first pin B+ is referred to as positive for supplying the positive potential of the output voltage VOUT and the second pin B− is referred to as negative for supplying the negative potential of the output voltage VOUT.

In order to connect the negative potentials together, the converter 114 comprises a second main busbar BP−, called negative main busbar, connecting the negative input pin B′− and the negative output pin B− together and to the negative line 222 of the conversion circuit 218.

The converter 114 further comprises a positive input main busbar BP′+ connecting the positive input pin B′+ to the input side of the positive branch 220 of the conversion circuit 218, and a first main busbar BP+, called positive output main busbar, connecting the positive output pin B+ to the output side of the positive branch 220 of the conversion circuit 218.

The converter 114 may further comprise a switch 228 for selectively connecting and disconnecting the positive main busbars BP+, BP′+. This allows the conversion circuit 218 to be short-circuited so that the output voltage VOUT is equal to the input voltage VIN. This function is useful, for example, when the recharging station 110 supplies an input voltage VIN that is already at the voltage required for recharging the battery 108.

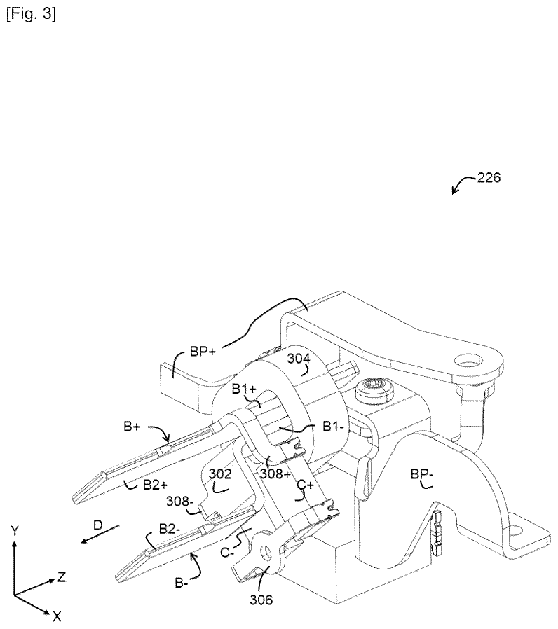

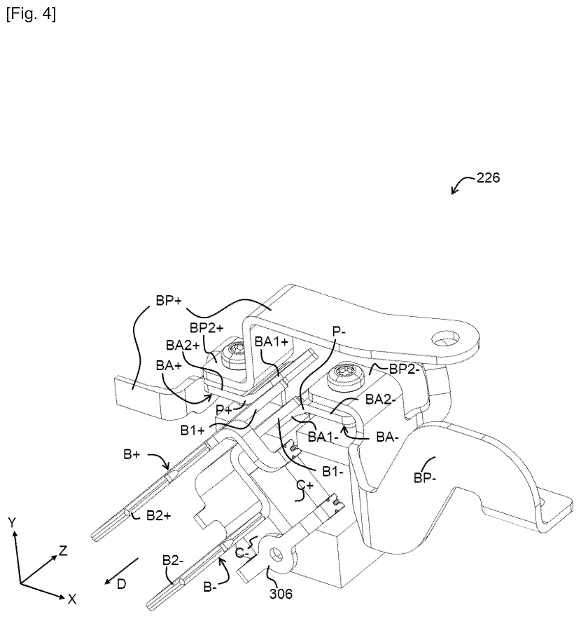

With reference to FIGS. 3 and 4, the output connector 226 will now be described in further detail.

With reference to FIG. 3, the output pins B+, B− respectively comprise, for example, two flat busbars, for example, ranging between 1 mm and 5 mm thick, for example, 4 mm thick, each having a flat fixing portion B1+, B1− and a flat end portion B2+, B2−. The end portions B2+, B2− project, for example, towards the outer space 210 along an axis D (in the forward direction in the illustrated example) and are designed to be connected to the additional connector of the output connector 226 along this axis D. In other embodiments, the end portions B2+, B2− could have a geometry other than a flat geometry, for example, a circular-section rod geometry projecting along the axis D.

The flat fixing portions B1+, B1− extend substantially parallel, for example, to the nearest 1°, opposite each other, for example, less than 10 mm apart, for example, 4 mm apart. Similarly, the flat end portions B2+, B2− extend substantially parallel, for example, to the nearest 1°, opposite each other, but at a greater distance than the flat fixing portions B1+, B1−, for example, at least twice as great, for example, between 20 mm and 30 mm from each other, for example, 25.7 mm from each other. For example, one of the output pins B+, B− (for example, the positive output pin B+, as in the illustrated example) is flat, while the other one of the output pins B+, B− (for example, the negative connection pin B−, as in the illustrated example) has a junction 302 between the end portion B2− and the fixing portion B1−, with this junction 302 having two bends, for example, made by folding the connection pin B− across its width.

The output connector 226 further comprises a first electromagnetic compatibility filter. This first filter firstly comprises, for example, a magnetic torus 304 surrounding the output pins B+, B−, and more specifically the fixing portions B1+, B1− due to their limited spacing. The first filter further comprises, for example, two capacitors C+, C− connected between a busbar 306 connected to an electrical ground (for example, the housing 202) and the positive output pin B+ and the negative output pin B−, respectively. For example, the positive output pin B+ comprises a tab 308+ extending from the flat busbar to the capacitor C+. Similarly, the negative output pin B− may comprise a tab 308− extending from the flat busbar to the capacitor C−. These tabs 308+, 308− are located between the magnetic torus 304 and the end portions B2+, B2− of the output pins B+, B−.

With reference to FIG. 4, the output connector 226 further comprises two auxiliary busbars BA+, BA−. The first BA+ is referred to as positive and is interposed between the positive pin B+ and the positive main busbar BP+. The second BA− is referred to as negative and is interposed between the negative pin B− and the negative busbar BP−.

Thus, each auxiliary busbar BA+, BA− comprises a first flat portion BA1+, BA1− fixed to the positive pin B+ and the negative pin B−, respectively, and more specifically to its fixing portion B1+, respectively B1−. The flat portions BA1+, BA1− of the auxiliary busbars BA+, BA− are, for example, pressed and fixed against faces of the fixing portions B1+, B1−. For example, the fixing portions B1+, B1− have opposite faces (facing each other) and external faces on the other side of the opposite faces. Thus, the flat portions BA1+, BA1− of the auxiliary busbars BA+, BA− are, for example, pressed and fixed against these external faces (as in the illustrated example).

Each auxiliary busbar BA+, BA− further comprises a second flat portion BA2+, BA2−. These second flat portions BA2+, BA2− are substantially parallel, for example, to the nearest 1°, to each other, for example, they are coplanar. Depending on the orientation of the output pins B+, B− about their axis D, each portion BA2+, BA2− may extend in the continuity of the first flat portion BA1+, BA1− (in which case the auxiliary busbars BA+, BA− are flat) or even at a non-flat angle (as in the illustrated example). In the latter case, each auxiliary busbar BA+, BA− has, for example, a fold P+, P− between the portions BA1+, BA2+ and BA1−, BA2−, substantially parallel to the axis D, for example, to the nearest 1°.

Flat portions BP2+, BP2− of the main busbars BP+, BP−, respectively, are respectively pressed and fixed against the second portions BA2+, BA2− of the auxiliary busbars BA+, BA−. Since the second portions BA2+, BA2− extend in parallel, they may be fixed in a similar manner, in particular along the same fixing axis, irrespective of the orientation of the output pins B+, B− about the axis D. In particular, when this fixing is completed by screwing (as in the illustrated example), the screwing may be carried out along the axis perpendicular to the second portions BA2+, BA2−, vertically in the illustrated example. This screwing axis also may be used for other screws of the converter 114. Thus, the same tool may be used to carry out all these screwing operations, irrespective of the orientation of the pins B+, B− about their axis D.

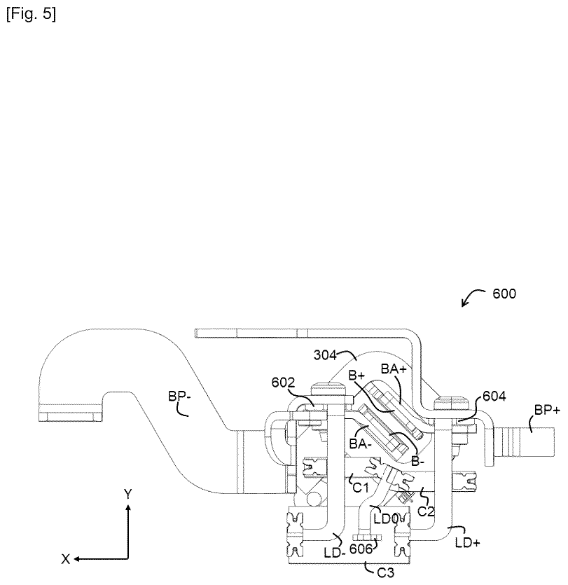

With reference to FIG. 5, the converter 114 further comprises a second electromagnetic compatibility filter 600 for the output connector 226.

This electromagnetic compatibility filter 600 firstly comprises a negative busbar LD− connected to the negative main busbar BP−. To this end, the negative busbar LD− comprises, for example, a fixing terminal 602 fixed to the negative main busbar BP−, for example, by the same screw as the negative auxiliary busbar BA−. The electromagnetic compatibility filter 600 further comprises a positive busbar LD+ connected to the positive main output busbar BP+. To this end, the busbar LD+ comprises, for example, a fixing terminal 604 fixed to the positive main output busbar BP+, for example, by the same screw as the positive auxiliary busbar BA+. The electromagnetic compatibility filter 600 further comprises a ground busbar LD0 connected to the electrical ground, for example, to the housing 202. To this end, the ground busbar LD0 comprises a fixing terminal 606 fixed to the electrical ground.

The electromagnetic compatibility filter 600 further comprises a capacitor C1 connected between the negative busbar LD− and the ground busbar LD0, a capacitor C2 connected between the positive busbar LD+ and the ground busbar LD0, and a capacitor C3 connected between the positive busbar LD+ and the negative busbar LD−. All the capacitors C1, C2, C3 have, for example, respective housings of generally parallelepiped shape with horizontal upper faces, parallel to each other, perpendicular to the Y axis.

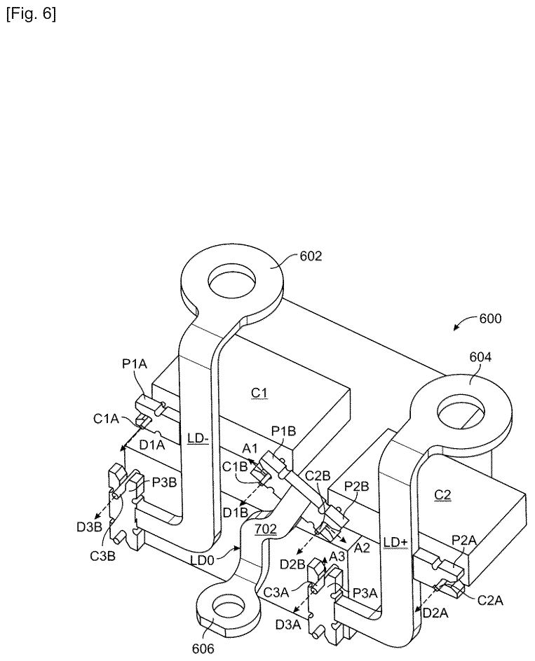

With reference to FIG. 6, in order to be connected, the capacitor C1 comprises two pins C1A, C1B projecting along axes D1A, D1B, parallel to the Z axis in the example shown. Thus, the negative busbar LD− comprises a clamp P1A clamping the pin C1A and the ground busbar LD0 has a clamp P1B clamping the pin C1B. The clamp P1B projects, i.e., opens, along an axis, called oblique axis, and in a direction A1 along this axis.

Similarly, in order to be connected, the capacitor C2 comprises two pins C2A, C2B projecting along axes D2A, D2B. Thus, the positive busbar LD+ comprises a clamp P2A clamping the pin C2A and the ground busbar LD0 comprises a clamp P2B clamping the pin C2B. The clamp P2B projects, i.e., opens, along the same axis, for example, to the nearest 1°, as the axis of the clamp P1B, and in a direction A2. The clamps P1B and P2B are positioned head-to-tail, i.e., the directions A1, A2 are opposite.

Similarly, in order to be connected, the capacitor C3 comprises two pins C3A, C3B (each of which can be split as in the example shown) projecting in forward directions D3A, D3B. Thus, the positive busbar LD+ has a clamp P3A clamping the pin C3A. This clamp P3A projects, i.e., opens, along the vertical axis Y in the upwards direction A3. The negative busbar LD− also has a clamp P3B that projects, i.e., opens, along the vertical axis Y in the upwards direction A3 and clamping the pin C3B.

The ground conductor LD0 comprises an elongate body 702 extending downwards from the clamps P1B, P2B, at least as far as the pin C3A. For example, the terminal 606 of the ground conductor LD0 is located lower than this pin C3A, such that the elongate body 702 passes to the side of the pin C3A and between the pins C3A and C3B.

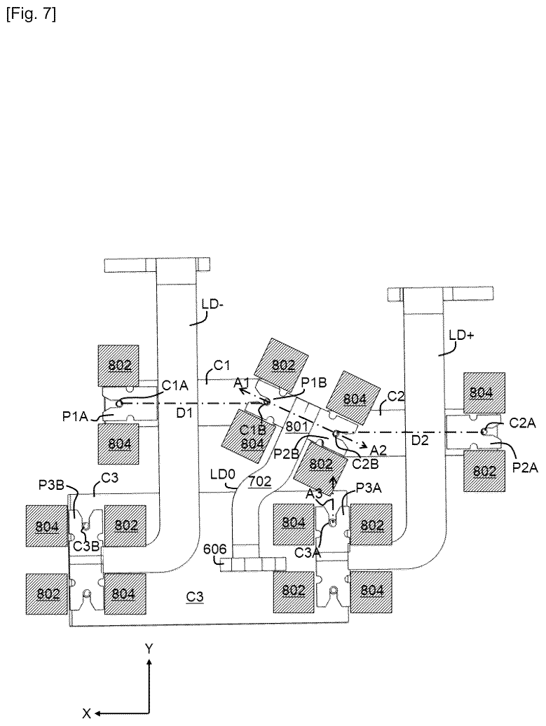

However, with reference to FIG. 7, when manufacturing the electromagnetic compatibility filter 600, each clamp P1A, P1B, P2A, P2B, P3A, P3B is closed on its associated pin C1A, C1B, C2A, C2B, C3A, C3B by a tool, in particular a fixing clamp having two elements 802, 804 designed to be respectively placed on each side of the clamp P1A, P1B, P2A, P2B, P3A, P3B. The fixing clamp may be a clamping clamp, in which case the elements are designed to move towards each other in order to mechanically push the two arms of the clamp P1A, P1B, P2A, P2B, P3A, P3B, respectively, so that they clamp the associated pin C1A, C1B, C2A, C2B, C3A, C3B. The fixing clamp also may be an electric soldering clamp, in which case the elements 802, 804 additionally or alternatively form electrodes for passing a current through the clamp P1A, P1B, P2A, P2B, P3A, P3B and the associated pin C1A, C1B, C2A, C2B, C3A, C3B in order to solder them together.

Thus, in order to leave sufficient space for these elements 802, 804, the elongate body of the ground busbar LD0 must pass at a distance from the clamp P3A.

In addition, in order for the electromagnetic compatibility filter 600 to be as compact as possible, it is recommended that the capacitors C1 and C2, which extend above the capacitor C3, are as close as possible to said capacitor C3.

In order to satisfy these two constraints, the capacitor C1 is positioned so that its pin C1B is higher than the pin C2B of the second capacitor C2. Thus, the opposite directions A1, A2 and the direction A3 together form an angle of less than 80°, preferably less than 70°, for example, 65°, which allows the elongate body 702 to have a straight end portion 801, from which the clamps P1B, P2B project substantially perpendicularly, for example, to the nearest 1°, which is vertically angled away from the clamp P3A. Thus, it is possible to keep a sufficient distance between the clamp P3A and the elongate body 702 for the passage of the elements 802, 804 (in particular the element 804) of the tool, while keeping the capacitor C2 low, close to the capacitor C3.

For example, the capacitor C1 is positioned so that its upper face extends higher than the upper face of the capacitor C2, i.e., to a greater height. For example, the height of the upper face of the capacitor C1 is at least 5 mm, preferably at least 10 mm, higher than the height of the upper face of the capacitor C2.

Still for example, the pins of each capacitor C1, C2 define a straight line D1, D2. These two straight lines D1, D2 are substantially parallel, for example, to the nearest 1°, with the line D1 above the line D2, for example, at least 5 mm above, for example, between 5 mm and 10 mm above.

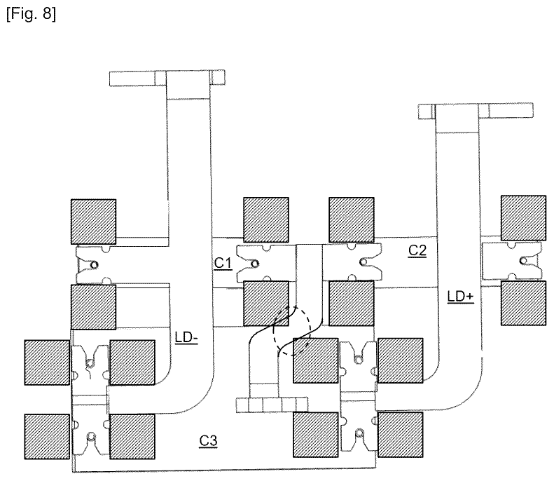

With reference to FIG. 8, if the capacitor C1 was positioned at the same level as the capacitor C2, the elongate body 702 would extend too close to the clamp P1B and/or to the clamp P3A to allow the passage of the tool elements 802, 804 (see the dashed circled area).

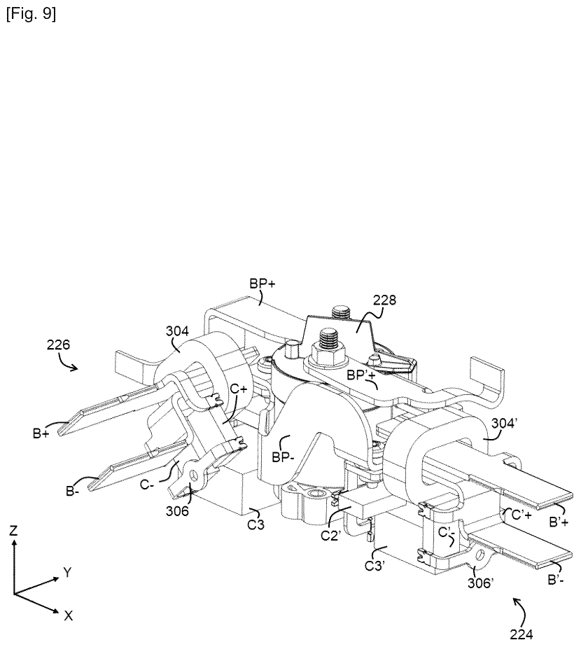

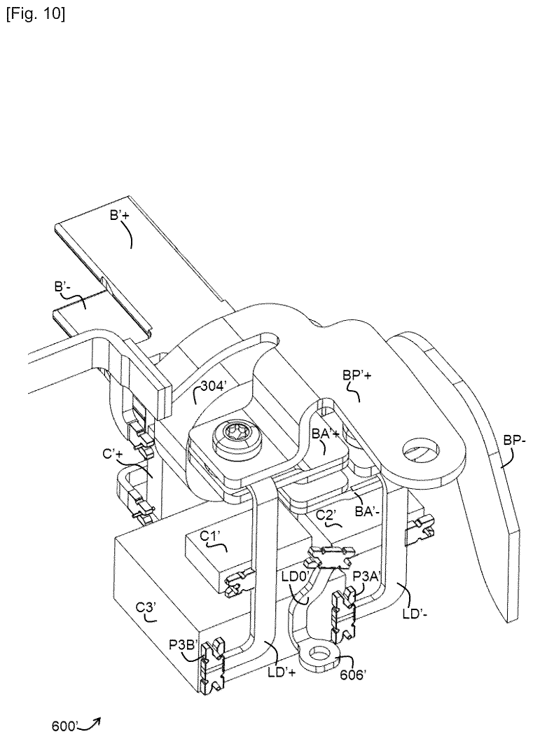

With reference to FIGS. 9 and 10, the input connector 224 has elements similar to those of the output connector 226, for which the reference signs of the previous figures are repeated, with “′” to distinguish them. The input pins B′+, B′− are identical to the output pins B+, B′, and in particular assume the same shape. The input pins B′+, B′− extend horizontally, i.e., perpendicular to the fixing direction (for example, screwing). Thus, no angle needs to be compensated, so that the auxiliary busbars BA′+, BA′− are flat.

In addition, an electromagnetic compatibility filter 600′ is also provided behind the input connector 224 and has elements similar to those of the electromagnetic compatibility filter 600, for which the reference signs of the preceding figures are repeated, with “′” to distinguish them. In particular, as before, the capacitors C1′, C2′ are vertically offset in order to facilitate the passage of the busbar LD0′ at a distance from the clamp.

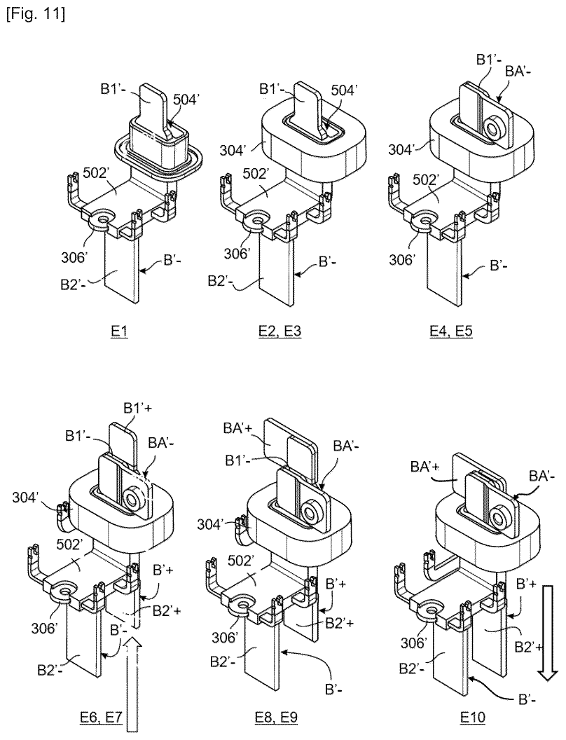

An example of a method for manufacturing the input connector 224 is described with reference to FIG. 11.

The output connector 226 is obtained by an identical method.

During a step E1, the negative pin B′− and, for example, the busbar 306′ are obtained. Both are obtained, for example, overmoulded with an overmoulding 502′, exposing the portions B1′−, B2′− of the negative pin B′−. The overmoulding 502′ also has a through opening 504′ in a portion of the overmoulding 502′ overmoulding the portion B1′− of the negative pin B′−. In other embodiments, the overmoulding 502′ could be devoid of a through opening 504′.

The magnetic torus 304′ is obtained during a step E2.

During a step E3, the negative pin B′− is inserted into the magnetic torus 304′ by its fixing portion B1′−, for example, until the torus 304′ extends around the overmoulding 502′, for example, around the portion of the overmoulding 302′ having the through opening 504′.

The negative auxiliary busbar BA′− is obtained during a step E4.

During a step E5, the portion BA1′− of the negative auxiliary busbar BA′− is pressed and fixed against the fixing portion B1′− of the negative pin B′−. The fixing is carried out, for example, by soldering, for example, by electric brazing and/or by depositing a silver link between the two portions BA1′−, B1′− to be fixed.

The positive branch B′+ comprising portions B1′+, B2′+ is obtained during a step E6.

During a step E7, the positive pin B′+ is inserted into the torus 304′ by its fixing portion B1′+, by offsetting, for example, upwards as in the illustrated example, its fixing portion B1′+ from the fixing portion B1′− of the negative pin B′−. In particular, as in the illustrated example, the positive pin B′+ is inserted into the through opening 504′ of the overmoulding 502′, such that the torus 304′ surrounds the fixing portion B1′+ of the positive pin B′+.

The positive auxiliary busbar BA′+ is obtained during a step E8.

During a step E9, the portion BA1′+ of the positive auxiliary busbar BA′+ is pressed and fixed against the fixing portion B1′+ of the positive pin B′+. This fixing is facilitated by the offset between the fixing portions B1′+, B1′− of the pins B′−, B′+, which allows access from both sides. Fixing is achieved by soldering, for example.

During a step E10, the positive pin B′+ is caused to slide down into the torus 304′ in order to place the fixing portions B1′+, B1′− opposite each other. For example, as in the example shown, the positive pin B′+ is caused to slide down into the through opening 504′ of the overmoulding 502′.

Once the connector 226 has been obtained by the method for manufacturing a connector as described above, this connector is assembled on the two main positive BP+ and negative BP− busbars of the DC-DC voltage converter 114 according to an assembly method comprising a step F1 of obtaining a connector 226 according to the method for manufacturing a connector as described above, and a step of pressing and fixing the flat portion BP2+ of the positive main busbar BP+ and the flat portion BP2− of the negative main busbar BP− against the second flat portions BA2+, BA2−, respectively, of the auxiliary busbars BA+, BA−.

In particular, this step of pressing and fixing the flat portion BP2+ of the positive main busbar BP+ and the flat portion BP2− of the negative main busbar BP− against the second portions BA2+, BA2−, respectively, of the auxiliary busbars BA+, BA− comprises a step of fixing by screwing the second portions BA2+, BA2− of the auxiliary busbars BA+, BA− to the flat portions BP2+, BP2− of the main busbars BP+, BP− in a screwing direction that is substantially perpendicular to the second portions BA2+, BA2− of the auxiliary busbars BA+, BA−.

It also should be noted that the invention is not limited to the embodiments described above. Indeed, it will be apparent to a person skilled in the art that various modifications may be made to the embodiments described above, in the light of the teaching that has just been disclosed to them.

In the detailed presentation of the invention provided above, the terms that were used must not be understood to be limiting the invention to the embodiments disclosed in the present description, but must be understood to be including all the equivalents conceivable by a person skilled in the art applying their general knowledge to the implementation of the teaching that has just been disclosed to them.

1. DC-DC electrical converter comprising:
an electrical conversion circuit designed to convert a DC input voltage into a DC output voltage;
an input or output connector, called first connector, comprising:
two pins, one positive and the other negative, designed to receive the input voltage or to supply the output voltage; and
two flat auxiliary busbars, one positive and the other negative, with each flat auxiliary busbar comprising a first flat portion pressed and fixed against the positive pin and the negative pin, respectively, and a second flat portion, with these second flat portions being substantially parallel to each other, for example, coplanar, with the first flat portion of the positive flat auxiliary busbar being pressed and fixed against a flat fixing portion of the positive pin, and the first flat portion of the negative flat auxiliary busbar being pressed and fixed against a flat fixing portion of the negative pin and comprising a connection portion directly adjacent to the first portion and to the second portion; and
two positive and negative main busbars connected to the electrical conversion circuit and respectively comprising flat portions respectively pressed and fixed against the second portions of the auxiliary busbars.

2. DC-DC electrical converter according to claim 1, the connection portion of each auxiliary busbar comprises a fold such that the first portion and the second portion of each auxiliary busbar together form a non-flat angle.

3. DC-DC electrical converter according to claim 2, wherein the connection portion comprises a single fold connecting the first portion and the second portion of each auxiliary busbar.

4. DC-DC electrical converter according to claim 1, the connection portion of each auxiliary busbar is, in a current circulation direction within the auxiliary busbar, shorter than the first portion and the second portion of the auxiliary busbar.

5. DC-DC electrical converter according to claim 1, wherein the second portions of the auxiliary busbars are fixed to the main busbars by screwing in a screwing direction that is substantially perpendicular to the second portions of the auxiliary busbars.

6. DC-DC electrical converter according to claim 1, wherein the first portions of the auxiliary busbars are fixed to the flat fixing portions of the pins by soldering.

7. DC-DC electrical converter according to claim 1, comprising a housing provided with a bottom with at least one flat part, and wherein the second portions of the auxiliary busbars are substantially parallel to the flat part of the bottom.

8. DC-DC electrical converter according to claim 1, wherein the flat fixing portions of the pins extend substantially parallel to each other one opposite the other and have opposite faces and outer faces, on the other side of the opposite faces, against which the first portions of the auxiliary busbars are pressed and fixed.

9. DC-DC electrical converter according to claim 8, wherein each pin comprises a flat end portion, with said end portions extending substantially parallel to each other one opposite the other, at a greater distance than the fixing portions, and wherein the connector further comprises a magnetic torus surrounding the fixing portions of the pins.

10. DC-DC electrical converter according to claim 9, wherein the connector further comprises:
a first capacitor connected between the positive pin and an electrical ground, with this first capacitor being connected to the positive pin between the magnetic torus and its end portion; and/or
a second capacitor connected between the negative pin and electrical ground, with this second capacitor being connected to the negative pin between the magnetic torus and its end portion.

11. DC-DC electrical converter according to claim 1, comprising another input or output connector, similar to the first connector, with the first and second flat portions of the auxiliary busbars of this other connector together forming an angle different from the angle between the first and second flat portions of the first connector, such that the second flat portions of this other connector are parallel to those f the first connector.

12. DC-DC electrical converter according to claim 11, wherein the positive pins and the negative pins of the two connectors are identical, in particular of the same shape.

13. Mobility vehicle comprising a DC-DC electrical converter according to claim 1.

14. DC-DC electrical converter according to claim 2, the connection portion of each auxiliary busbar is, in a current circulation direction within the auxiliary busbar, shorter than the first portion and the second portion of the auxiliary busbar.

15. DC-DC electrical converter according to claim 2, wherein the second portions of the auxiliary busbars are fixed to the main busbars by screwing in a screwing direction that is substantially perpendicular to the second portions of the auxiliary busbars.

16. DC-DC electrical converter according to claim 2, wherein the first portions of the auxiliary busbars are fixed to the flat fixing portions of the pins by soldering.

17. DC-DC electrical converter according to claim 2, comprising a housing provided with a bottom with at least one flat part, and wherein the second portions of the auxiliary busbars are substantially parallel to the flat part of the bottom.

18. DC-DC electrical converter according to claim 2, wherein the flat fixing portions of the pins extend substantially parallel to each other one opposite the other and have opposite faces and outer faces, on the other side of the opposite faces, against which the first portions of the auxiliary busbars are pressed and fixed.

19. DC-DC electrical converter according to claim 2, comprising another input or output connector, similar to the first connector, with the first and second flat portions of the auxiliary busbars of this other connector together forming an angle different from the angle between the first and second flat portions of the first connector, such that the second flat portions of this other connector are parallel to those of the first connector.

20. Mobility vehicle comprising a DC-DC electrical converter according to claim 2.
